(19) United States
(12) Patent Application Publication
(10) Pub. No.: US 2020/0090933 A1
(43) Pub. Date: Mar. 19, 2020

(54) CRYSTALLINE TRANSITION METAL DICHALCOGENIDE FILMS AND METHODS OF MAKING SAME

(71) Applicants: Christopher Muratore, Dayton, OH (US); Michael E. McConney, Beavercreek, OH (US); Travis E. Shelton, Dayton, OH (US); Nicholas R. Glavin, Beavercreek, OH (US); John E. Bultman, Huber Heights, OH (US); Andrey A. Voevodin, Dayton, OH (US)

(72) Inventors: Christopher Muratore, Dayton, OH (US); Michael E. McConney, Beavercreek, OH (US); Travis E. Shelton, Dayton, OH (US); Nicholas R. Glavin, Beavercreek, OH (US); John E. Bultman, Huber Heights, OH (US); Andrey A. Voevodin, Dayton, OH (US)

(73) Assignee: University of Dayton, Dayton, OH (US)

(21) Appl. No.: 16/527,326

(22) Filed: Jul. 31, 2019

Related U.S. Application Data
(63) Continuation of application No. 15/962,445, filed on Apr. 25, 2018, now abandoned.
(60) Provisional application No. 62/489,799, filed on Apr. 25, 2017.

(51) Int. Cl. H01L 21/02; H01L 29/24

(52) U.S. Cl. CPC H01L 21/02675; H01L 21/02568; H01L 21/02485; H01L 21/02631; H01L 21/02422; H01L 29/24

(57) ABSTRACT

Methods of making molybdenum sulfide (MoS₂) on a stretchable substrate are disclosed. The method includes magnetron sputtering MoS₂ onto a stretchable substrate, such as a stretchable polymeric material, at low temperatures to form a film precursor, and illumination annealing the film precursor to form high quality MoS₂. The illumination source may be a laser or other source of radiation. Also, two-dimensional nanoelectronic devices made by the methods and/or from the high quality MoS₂ are disclosed.

### CROSS REFERENCE TO RELATED APPLICATIONS

This application is a continuation of U.S. patent application Ser. No. 15/962,445, filed on Apr. 25, 2018, which in turn claims priority to U.S. Provisional Application No. 62/489,799, filed on Apr. 25, 2017. The contents of these applications are hereby incorporated by reference in their entirety as part of this application.

### FEDERALLY SPONSORED RESEARCH

This invention was made with U.S. Government support under Contract Number RX18-UD-14-3-AFRL awarded by DAGSI/Air Force Research Laboratory. The U.S. Government may have certain rights in the invention.

### TECHNICAL FIELD

The present application relates generally to methods of making transition metal dichalcogenide (“TMD”) films on stretchable polymeric materials, more particularly to methods for growing continuous, few-layer TMDs at low temperatures by forming a precursor film that is subsequently laser annealed.

### BACKGROUND

Atomic-scale transition metal dichalcogenides (“TMDs”), for example molybdenum disulfide (MoS₂) and tungsten sulfide (WS₂), are promising semiconductors for flexible and/or stretchable electronic devices, such as displays and wearable sensors. Stretchable devices are typically generated through exfoliation or through lift-off methods, but these approaches are not commercially viable. Currently, commercial scale growth of high quality transition metal dichalcogenide films requires high temperatures, which is not compatible with stretchable polymeric materials.

Processes employing temperatures no higher than 250° C. are needed to generate TMD films on most flexible and/or stretchable substrates because higher temperatures can degrade such substrates. Very thin films of TMDs made at low temperatures generally do not show desirable two-dimensional characteristics, such as direct band gap, photoluminescence, or large response to changes in surface potential due to low subthreshold swing when incorporated into electronic devices. Such thin films do exhibit compositional and thickness uniformity, as well as hole-free morphology, but the films lack the atomic ordering or crystallinity required for desired electronic properties.

Accordingly, new methods of making high quality TMD films are needed that are compatible with stretchable polymeric materials and that provide a TMD film with two-dimensional characteristics for desired electronic properties.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The claimed subject matter is described with reference to the accompanying drawings. A brief description of each figure is provided below. Elements with the same reference number in each figure indicate identical or functionally similar elements.

FIG. 1 is a schematic illustration of a method disclosed herein.

FIG. 2 is a Raman spectra comparing a molybdenum sulfide film made according to FIG. 1 before and after the laser annealing process.

FIG. 3 is chart of resistance as the temperature decreases for a molybdenum sulfide film after laser annealing, showing its semiconductive property.

FIG. 4 is a graph showing conductive atomic force microscopy measurements comparing a molybdenum sulfide film made according to FIG. 1 before and after the laser annealing process.

FIG. 5 is a Raman spectra comparison of molybdenum sulfide films made according to the method of FIG. 1 having the same total 50 mW-sec dosage, but different laser powers and exposure time.

FIG. 6 is an optical microscopy image of a sample with laser annealed lines of crystalline molybdenum sulfide.

FIG. 7 is a Raman map of the sample of FIG. 4 where the intensity corresponds to the intensity of the A_{1g} peak.

FIG. 8 is a TEM image taken in cross-section of laser annealed molybdenum sulfide film on a polydimethylsiloxane substrate.

FIG. 9 is a Raman spectra from a vertical molybdenum sulfide/tungsten sulfide heterostructure grown according to the method of FIG. 1.

FIG. 10 is an image of ring patters of crystalline material from pulsed laser annealing.

### DETAILED DESCRIPTION

The following detailed description will illustrate the general principles of the invention, examples of which are additionally illustrated in the accompanying drawings. In the drawings, like reference numbers indicate identical or functionally similar elements.

Laser or illumination-based annealing processes are disclosed herein that solve the problems discussed in the background section, in particular the problems related to transition metal dichalcogenide films on flexible polymeric substrate material. The methods convert very thin, amorphous TMD films (films with a thickness <10 nm) prepared by a physical vapor deposition process at a temperature in a range of about 20° C. to about 250° C., more preferably about 25° C. to about 200° C., to crystalline TMD films. The crystalline TMD films may be single- and/or poly-crystalline and have a few monolayer thicknesses over large areas.

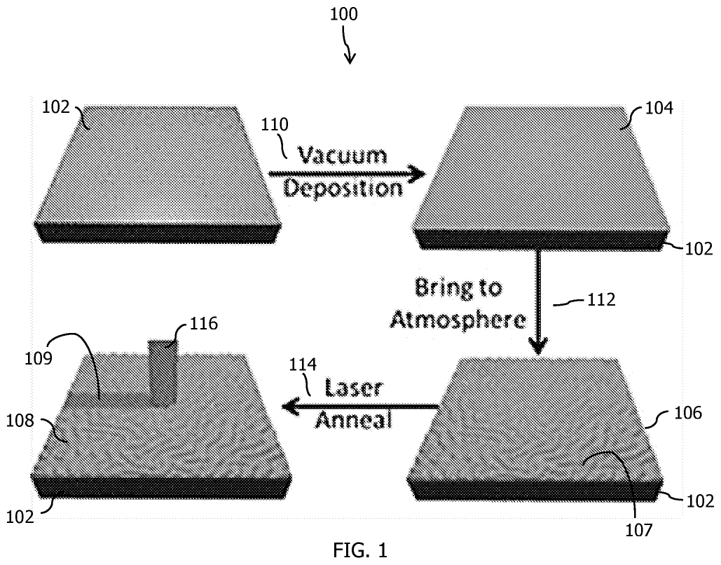

Referring now to FIG. 1, the method includes providing a precursor film 106 comprising an amorphous transition metal dichalcogenide film 107 deposited on a substrate 102 by a physical vapor deposition process 110 at a temperature in a range from about 20° C. to about 250° C., more preferably about 25° C. to about 200° C., and illuminating the film (with a laser or other light source, including but not limited to continuous wave lasers, pulsed lasers, and broadband lamps) to anneal the precursor film 106, thereby changing the amorphous transition metal dichalcogenide film 107 to a crystalline transition metal dichalcogenide film 109. The method may include forming the precursor film by a physical vapor deposition process 110 and subsequently returning the precursor film to atmosphere pressure 112. The steps illustrated in FIG. 1 are generally similar for other illumination sources.

The physical vapor deposition is typically conducted under vacuum and may include magnetron sputtering, pulsed laser deposition, thermal evaporation, electron beam evaporation, or other processes that deposit an initially solid source material on a substrate as a film. The physical vapor deposition deposits an amorphous transition metal dichalcogenide film 104 having a thickness less than 10 nm. The transition metal dichalcogenide film can include one or more of molybdenum sulfide and tungsten sulfide.

Generally, the physical vapor deposition includes loading a substrate material, such as a flexible and/or stretchable substrate material, and a solid material source or “target,” here a TMD, into a physical vapor deposition chamber which typically will be evacuated to vacuum. Then, the TMD precursor film is deposited via magnetron sputtering, pulsed laser deposition, thermal evaporation, electron beam evaporation, or some other physical vapor deposition process from the target, which may have the same or similar composition of the deposited film. The target composition may be different from the desired film composition as a result of adding additional elements in the vapor phase to the material ejected from the physical vapor deposition target (for example, a molybdenum physical vapor deposition target could be used in conjunction with a sulfur vapor source to produce an MoS₂ film). Multiple layers of ultrathin (from 0.5 to 50 nm) TMD films with different compositions may be applied during this stage, such as MoS₂/WS₂/MoS₂, or any combination in any order. These precursor films can be prepared with mid-frequency pulsed magnetron sputtering at room temperature as described in Alam et al., Domain engineering of physical vapor deposited two-dimensional materials, Applied Physics Letters, 105 (2014) 213110, Muratore et al., Continuous ultra-thin MoS₂ films grown by low-temperature physical vapor deposition, Applied Physics Letters, 104 (2014) 261604, and co-pending U.S. application Ser. No. 14/501,994, the disclosures of each of which are incorporated herein by reference.

Referring back to FIG. 1, the substrate with the deposited film 104 is then removed from the vacuum processing chamber and brought back to atmosphere pressure 112. The as-deposited amorphous TMD precursor films are subsequently laser annealed 114 by exposure to laser or other radiation 116. The annealing process includes exposure to radiation (for example, from a laser, lamp, or other light source) for durations ranging from 0.1 to 1000 seconds or 0.1 to 100 seconds with an intensity (power density) of about 0.1 mW/μm² to about 50 mW/μm², or about 0.5 mW/μm² to about 20 mW/μm², or about 2 mW/μm² to about 20 mW/μm², or about 10 mW/μm²to about 20 mW/μm². Upon laser annealing, the thin amorphous precursor films are converted to crystalline material. The lower limit on the size of photonically annealed areas is limited only by laser wavelength, and the upper limit is on the order of square meters. The entirety of the film may be annealed to form a continuous thin amorphous precursor film, or the radiation source may be controlled (selectively turned on and off) to form a pattern of crystalline transition metal dichalcogenide film in the precursor film. In one embodiment, the radiation source was a xenon lamp and the crystallization of the amorphous MoS₂ samples was 3 cm×3 cm.

One desirable substrate here is a flexible and/or stretchable substrate material. For applications such as wearable sensors, healthcare diagnostics, and monitoring food packaging, the substrate material may need to be a biocompatible substrate material. For applications such as displays and solar energy harvesting devices, a biocompatible substrate material is not necessary. The flexible and/or stretchable substrate material may be a polymeric material such as polydimethyl siloxane (PDMS), 2-methacryloyloxyethyl phosphorylcholine (MPC), or one or both thereof copolymerized with dodecyl methacrylate (DMA). In other examples, the flexible and/or stretchable substrate material may be a polyimide or perylene sheet.

It is worth noting that PDMS is transparent to the optical laser radiation (λ=514 nm) used in annealing the TMD in the working examples below. Thus, the surface of PDMS is unaffected by the radiation when the PDMS does not have a TMD film deposited thereon. For PDMS having the amorphous TMD film deposited thereon, the incident photon energy is absorbed by the film and photo-thermally driven crystallization occurs for power densities in the range of about 0.1 mW/μm² to about 50 mW/μm², about 0.5 mW/μm² to about 20 mW/μm², more preferably about 2 mW/μm² to about 20 mW/μm², and even more preferably about 10 mW/μm² to about 20 mW/μm².

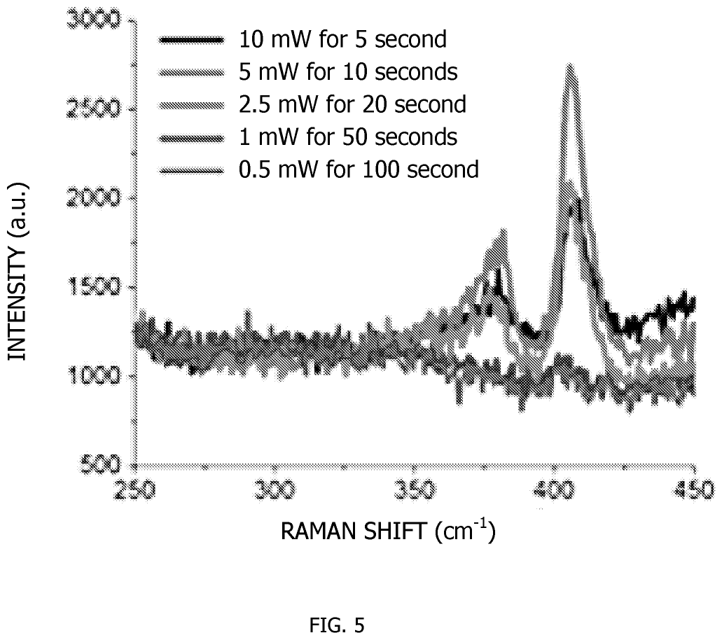

In the underlying process of the crystallization under laser or other illumination, irradiation annealing appears to be a thermally driven kinetic controlled transformation. Essentially, the thin films are quickly heated sufficiently to induce the transition of the amorphous TMD films to crystalline TMD films. The photothermal nature of the mechanism is supported by several critical observations. Firstly, the laser induced phase transformation is a non-linear process as it is not directly dependent on the dosage (i.e., fluence or time-integrated irradiance), but instead is highly dependent on the laser intensity (i.e., the irradiance in W/m²), see FIG. 5. Secondly, the assertion that the mechanism is a kinetically controlled photothermal effect is supported by the fact that the same results were achieved with different laser wavelengths, including 1064 nm at similar intensities to a 514 nm laser.

The TMD films made by the processes disclosed above can be included in an electronic device, flexible displays, solar energy harvesting devices, flexible molecular sensors for real-time human/animal performance evaluation, healthcare diagnostics, and monitoring of packaged foods, just to name a few examples. In any of these devices, the TMD film may be a patterned crystalline transition metal dichalcogenide film or a continuous crystalline TMD film and be on a flexible and/or stretchable substrate.

### WORKING EXAMPLES

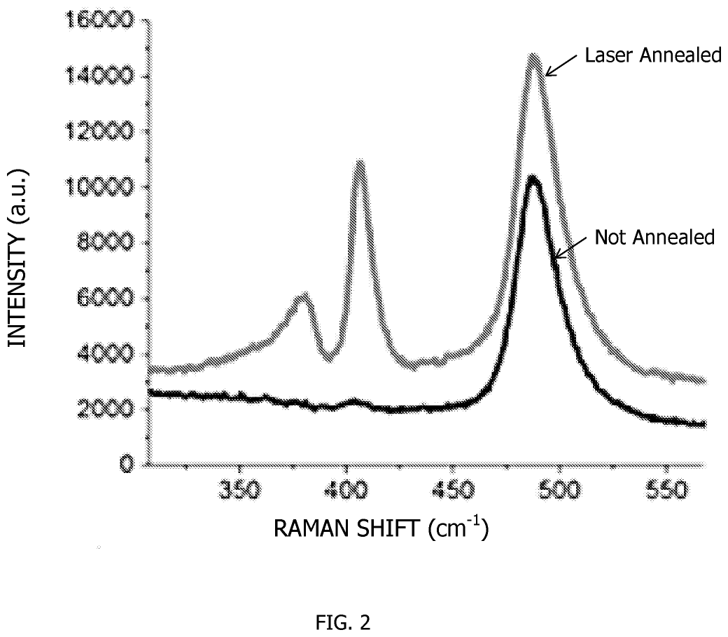

The data disclosed in FIGS. 2-8 is from an ultrathin crystalline molybdenum sulfide film on a polydimethyl siloxane substrate formed as disclosed herein. In particular, a molybdenum sulfide target was deposited as a film on a polydimethyl siloxane substrate via magnetron sputtering under vacuum at room temperature (approximately 23° C.), and subsequently, at atmospheric pressure, was laser annealed for a total dosage of 50 mW-sec with a 514 nm wavelength laser and an intensity of 1 kW/cm². FIG. 2 shows the difference in Raman spectra between the as-deposited ultrathin MoS₂ material and the MoS₂ after being laser annealed. The film thickness did not change as a result of the laser annealment; therefore, the increase in Raman intensity is entirely due to the structural change from amorphous to crystalline.

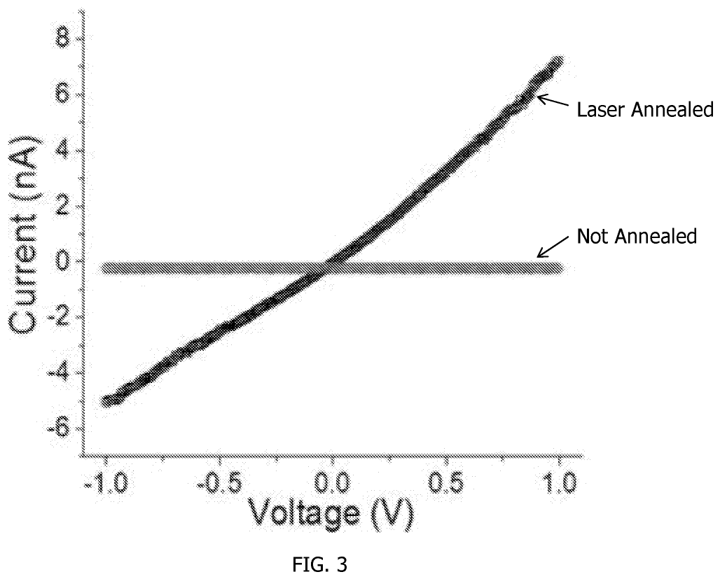

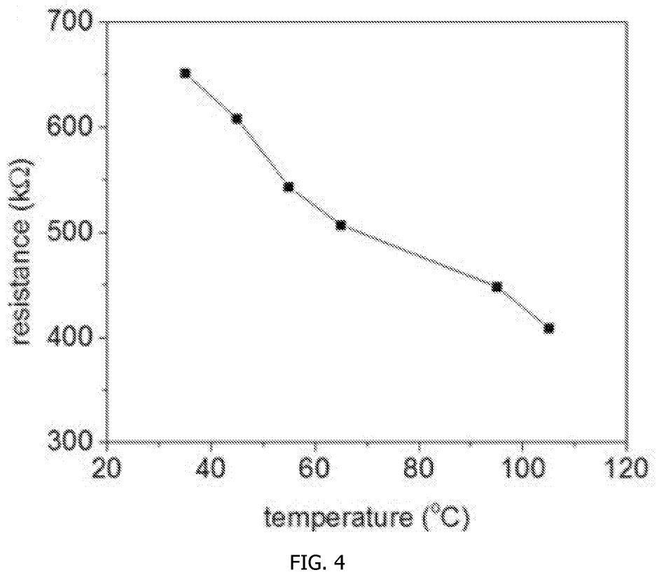

FIG. 3 is a graph of the conductive atomic force microscopy measurements showing a change in the electrical properties in the annealed MoS₂ film versus the as-grown amorphous MoS₂ film. The annealed MoS₂ film is semiconducting, and the as-grown amorphous MoS₂ film is electrically insulating. This demonstrates the ability to “write” semiconducting patterns in an amorphous film or matrix. As shown in FIG. 4, the resistance of the annealed MoS₂ film decreases with temperature, indicating its semiconducting property. Additionally, large areas can be treated with a rastering laser or with a large area, broad-band radiation source such as a xenon lamp to make large continuous areas of semiconducting film as all of the amorphous, insulating material is transformed by exposure to the radiation.

FIG. 5 compares the Raman spectra for a plurality of amorphous MoS₂ film samples laser annealed at different laser powers for different times for a total dosage of 50 mW-sec. It is quite evident that the annealing mechanisms of hexagonal structure formation in MoS₂ are a non-linear process, and evidenced a stronger Raman shift at laser powers above 1 mW.

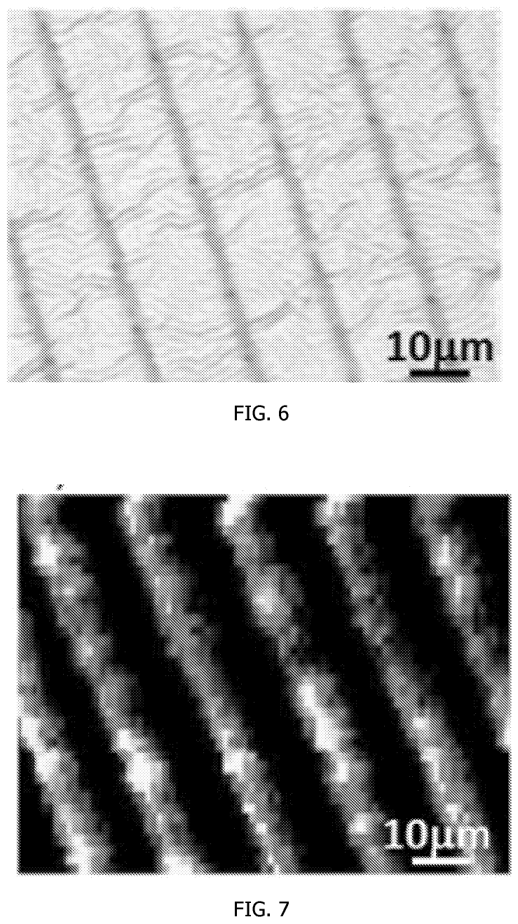

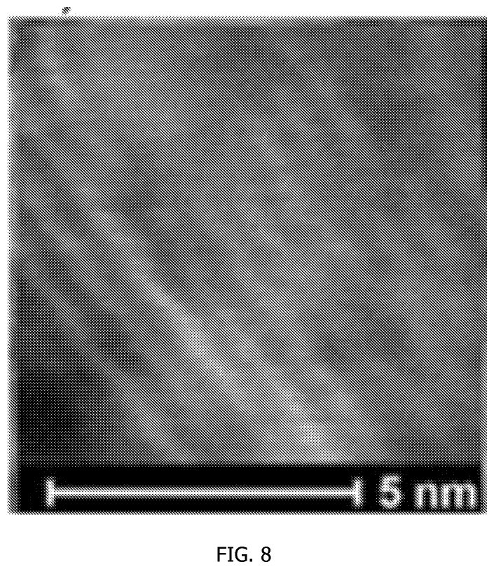

FIGS. 6 and 7 are optical micrographs of a sample with several laser annealed lines. The laser spot diameter was about 1.5 μm; however, there is no limit on laser spot diameter provided the power over the irradiated area is within a suitable, specified range. The writing speed was about 25 μm/s; however, a broad range of writing speeds is acceptable. Based on the A_{1g} peak identified in FIG. 5 of about 408 cm⁻¹, FIG. 7 is a Raman map of FIG. 6 where the intensity corresponds to 408 cm⁻¹.

FIG. 8 is a transmission electron microscopy cross-section of the laser annealed MoS₂ film on the PDMS substrate where white lines show atomic ordering of nine molecular layers of MoS₂.

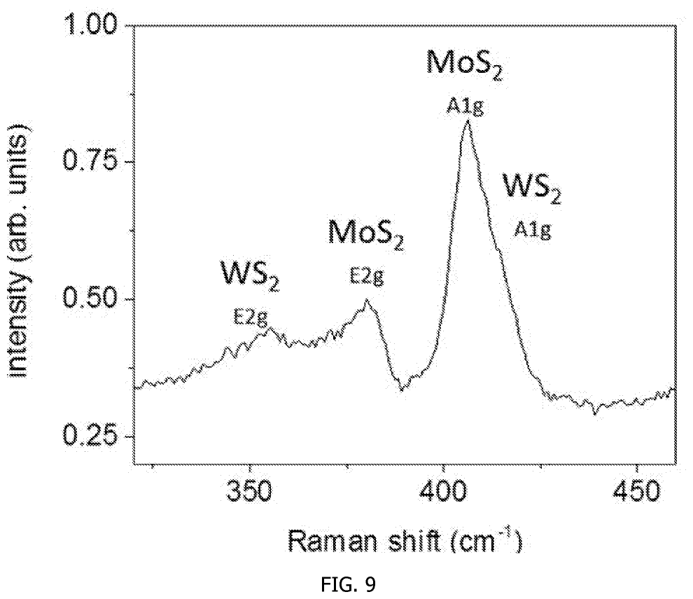

One important feature is the ability to modify multiple layers of as-grown TMD films with distinctive compositions with exposure to the laser. FIG. 9 is an example from a few layer MoS₂/WS₂ heterostructure showing the Raman spectrum grown in the same way as the monolithic coating described above for FIG. 2. Both top and bottom layers are crystallized during laser annealing of the film.

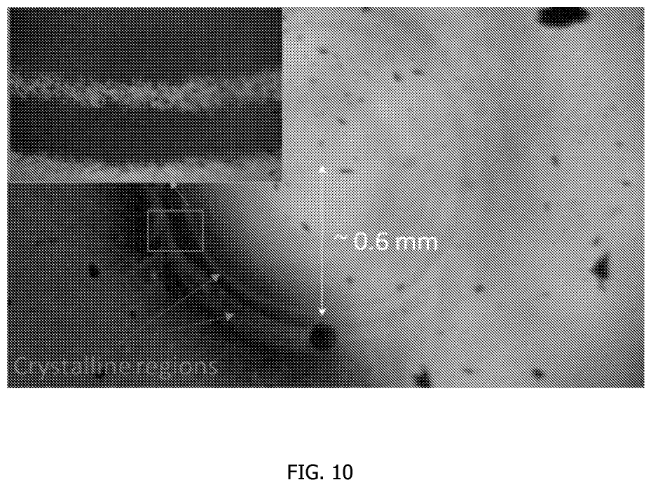

Referring now to FIG. 10, strain may be involved in the transformation of material from amorphous to continuous, as rings of crystalline material are observed in pulsed laser processing. The distance of the rings from the center of the incident beam appears to exhibit dependence on the stiffness of the PDMS, suggesting propagation of a shock wave from the incident laser may contribute to crystallization. This feature of pulsed laser processing could be used to directly fabricate devices such as bullseye plasmon antennas.

The methods and resulting MoS₂ films are suitable for flexible electronics such as two-dimensional semiconductors. These two-dimensional semiconductors possess a unique combination of electronic and mechanical properties for building flexible devices, such as a large, direct band gap and having up to about 10% mechanical strain. These devices may be used in flexible displays, solar energy harvesting, flexible molecular sensors for real-time human/animal performance evaluation, healthcare diagnostics, and monitoring of packaged foods.

The embodiments of this invention shown in the drawings and described above are exemplary of numerous embodiments that may be made within the scope of the appended claims. It is contemplated that numerous other configurations of the methods may be created taking advantage of the disclosed approach. In short, it is the Applicants' intention that the scope of the patent issuing herefrom be limited only by the scope of the appended claims.

What is claimed is:

1. A method for making a transition metal dichalcogenide film, the method comprising:
providing a precursor film comprising an amorphous transition metal dichalcogenide film deposited on a substrate by a physical vapor deposition process at a temperature in a range from about 20° C. to about 250° C.;
illumination-based annealing the precursor film, thereby changing the amorphous transition metal dichalcogenide film to a crystalline transition metal dichalcogenide film.

2. The method of claim 1, wherein the substrate is a flexible substrate material.

3. The method of claim 2, wherein the flexible substrate material comprises polydimethyl siloxane (PDMS), 2-methacryloyloxyethyl phosphorylcholine (MPC), or one or both copolymerized with dodecyl methacrylate (DMA).

4. The method of claim 1, wherein the physical vapor deposition is magnetron sputtering, pulsed laser deposition, thermal evaporation, or electron beam evaporation.

5. The method of claim 1, wherein the amorphous transition metal dichalcogenide film has a thickness less than 10 nm.

6. The method of claim 1, wherein the transition metal dichalcogenide film comprises one or more of molybdenum sulfide and tungsten sulfide.

7. The method of claim 1, wherein the laser annealing comprises exposing the amorphous transition metal dichalcogenide film to laser radiation having an intensity of about 0.5 mW/μm² to about 20 mW/μm² for about 0.1 to about 100 seconds.

8. The method of claim 7, wherein the intensity is in a range of about 2 mW/μm² to about 20 mW/μm².

9. The method of claim 1, wherein the intensity is in a range of about 10 mW/μm² to about 20 mW/μm².

10. The method of claim 1, wherein laser annealing comprises selectively turning an illumination source on and off repeatedly to form a pattern of crystalline transition metal dichalcogenide film in the precursor film.

11. The method of claim 10, wherein the illumination source is a laser.

12. An electronic device comprising a patterned crystalline transition metal dichalcogenide film made according to the method of claim 10.

13. An electronic device comprising a crystalline transition metal dichalcogenide film made according to the method of claim 1.

14. A sensor comprising a crystalline transition metal dichalcogenide film made according to the method of claim 1.

15. A sensor comprising a crystalline transition metal dichalcogenide film made according to the method of claim 2.
